(19) United States
(12) Patent Application Publication
(10) Pub. No.: US 2015/0340396 A1
(43) Pub. Date: Nov. 26, 2015

(54) Image sensor with dispersive color separation

(71) Applicant: Vladislav Blayvas, Jerusalem (IL)

(72) Inventor: Vladislav Blayvas, Jerusalem (IL)

(21) Appl. No.: 14/286,995

(22) Filed: May 24, 2014

(51) Int. Cl. H01L 27/146

(52) U.S. Cl. CPC H01L 27/14627; H01L 27/14621

(57) ABSTRACT

A converging composite lens with enhanced chromatic aberration comprising one or more converging lenses from flint glass, and one or more diverging lenses from crown glass. A dispersive composite prism with enhanced chromatic aberration, comprising two or more thin prisms, stacked one on atop another in alternating opposite directions, where the prisms in the first direction are produced from flint glass, and the prisms in the second direction are from crown glass. A color image sensor comprising color pixels with colors separated by such dispersive lenses or prisms. A concentric image pixel with concentric circular and ring shaped photo sensors.

### TECHNICAL FIELD

The present disclosure relates to solid state image sensors, and in particular to the color solid state CMOS and CCD array sensors.

### BACKGROUND

This invention is related to the art of digital imaging, and more specifically to the image sensors, which comprise an array of light sensitive elements converting incident light into the electrical signals.

### BRIEF SUMMARY

In the prior art image sensors the colors are obtained by deposition of the color filters over the pixels. Red sensitive pixels are covered by red filters that transmit red and absorb green and blue, green sensitive pixels are covered by green filters that transmit green and absorb red and blue, blue sensitive pixels are covered by blue filters that transmit blue and absorb red and green.

This solution suffered from several shortcomings: each color filter absorbs the light of complementary colors, and thus reduces the sensor sensitivity in low light, and increases the noise. Moreover, only one color is measured in each pixel, and information about two other colors is absent, which reduces the sensor resolutions, and creates color artifacts and ambiguity, especially along the edges and fine details of the image.

One of the goals of the present invention is to solve the limitations of the prior art, namely to prevent loss of the light absorbed in the color filters, and to prevent loss of information in color pixel, due to absorption of other colors in the color filter.

One of the embodiments of the current disclosure comprises a dispersive microlens placed over the concentric circle and ring-shaped light sensing elements. Due to the color dispersion of the microlens it has different focal lengths for different light wavelengths, usually with shortest focal length for blue and longest for red wavelengths.

In the preferred embodiment the microlens is constructed and placed above the layer of photo-sensors so, that the blue band is focused, forming the small spot in the center, the green band is less focused forming the larger sport, while the red band is even less focused, forming the largest blurred spot. The circular shaped photo sensors are placed accordingly, with blue circular-shaped center in the center, the green ring-shaped surrounding it, and the bigger ring-shaped red at the periphery around the green.

In other embodiments the number of color bands and their, their shape, and order may vary, as will be obvious to a person skilled in the art.

In yet another embodiment the color separation of the colors is weak or absent, but yet the concentric structure of the pixels is used for other benefits. The color separation may be added or completely performed by the appropriate color filters deposited over the concentric photo sensors.

The light-sensors are placed concentrically, so that the sensor corresponding to particular color band is placed in the area with dominant illumination in that band.

In other embodiments the shape, position and even quantity of color pixels may vary as will be obvious to a person skilled in the art. Furthermore, the color filters may be deposited over the color pixels, or other techniques like vertical semiconductor-thickness induced separation of colors may be applied to facilitate the color separation.

In another embodiment, the red band is focused in the center, while green band was focused above the photosensor plane, and forms a bigger spot around the center, while blue was focused even higher above the photosensor plane, and forms an even bigger spot. In yet other embodiments, other material is used for microlens with opposite or other refractive properties, and/or other optical element rather than the microlens is used to separate the colors, and/or other shape of light-sensing elements.

### BRIEF DESCRIPTION OF THE SEVERAL VIEWS OF THE DRAWINGS

FIG. 1 is a schematic drawing of the color pixel of image sensor array in accordance with one of the embodiments;

FIG. 2 is a schematic drawing of the color pixel of image sensor array in accordance with one of the embodiments of dispersive microlens;

FIG. 3 is a schematic drawing illustrating composite dispersive lens or microlens.

FIG. 4 is a schematic drawing illustrating composite dispersive prism or microprism.

### DETAILED DESCRIPTION

An array of light-sensitive pixels, converting an image created by an optical system into electrical signals is the heart of modern digital imaging systems. These light-converting arrays are known in the art as image sensors. Modern image sensors usually use silicon or other semiconductor material, which are light sensitive in the broad spectrum.

In order to create color-sensitive array, the light absorbing color filters are applied above the pixels. Usually those are Red, Green and Blue filters. Each filter transmits its dedicated color and absorbs two others. Therefore the pixels covered by Red filter is sensitive to Red light and non-sensitive to Green and Blue. Similarly pixels covered by Green and Blue filters are sensitive respectively to their color, and non-sensitive to the remaining colors.

Unfortunately this solution creates many severe problems in digital imaging: Absorbing two colors out of three over every pixel reduces the amount of light reaching the sensor at least by a factor of 3, and decreases its sensitivity in low light illumination, increasing the signal noise.

Another major shortcoming of color filters is the decrease of sensor spatial resolution due to the fact that only one color is known for each pixel, while two others are reconstructed by interpolation the values of the neighbor pixels. This shortcoming also causes color aliasing, when the false color artifacts are produced along the edges and fine details of the image.

For example small white spots falling onto the red pixels will be interpreted as red, small blue spots falling onto the greed pixels will be interpreted as black, the boundary between black and white regions will create color artifacts, due to non-even overlapping with color pixels along the boundary.

In the preferred notation of this disclosure the term ‘composite pixel’ denotes a pixel containing two or more separate pixels in separate color bands of the visible spectrum such as red, green, and blue. The composite pixel may also contain only two or more than three color bands, and the color bands may include invisible parts of the electro-magnetic spectrum, such as infra-red and/or ultra-violet, x-rays etc.

The color bands may be not perfectly separated, and may overlap, and each color pixel may possess some sensitivity in the other bands, as will be obvious to somebody skilled in the art. Furthermore, additional means for color separation, such as deposited color filters, or other color-separation means known in the art or invented in the future may be applied to the color pixels. Furthermore, the dispersive color separation effect may be small, negligible or absent, yet the present disclosure holds its validity due to other benefits.

Most refractive materials possess color dispersion, which is the change dependence of refraction coefficient on the wavelength. In the lens industry this phenomena is often considered as shortcoming, and various techniques to decrease or overcome it had been developed. However, in this disclosure we utilize it, by creating the dispersive micro-lenses over the concentric pixels.

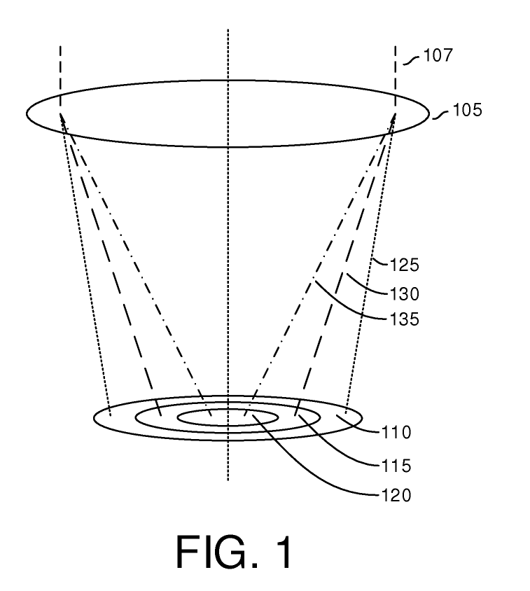

FIG. 1 illustrates the operation principle of one of the embodiments. The light beam 107 onto a micro-lens 105. Due to the microlens dispersion, the focusing is different for different color bands. The blue band 135 is focused on the center area, and sensed by the circular pixel 120. The Intermediate green band is less focused, and shaped into the wider spot, illustrated by the beams 130. It may partially overlap with the blue beam, however it will also have significant part of energy distributed on over the ring-shaped green-sensitive pixel 115. Finally the red band is even less focused, and forms an even larger spot, illustrated by beam 125, and sensed by peripheral ring-shaped red-sensitive pixel 110.

The color separation in the pixels maybe based exclusively on the color dispersion of the microlens, or maybe facilitated by additional means known in the art, such as deposited color filters [U.S. Pat. No. 3,971,065], alternated depth of light-sensitive layer or stacked structure of the light-sensitive diodes, based on the fact that absorption coefficient of the photon in the semiconductor varies with the wavelength [U.S. Pat. No. 5,965,875].

Although FIG. 1 illustrates circular and ring-like geometry of the pixels, it will be obvious to skilled in the art, that other geometries such as rectangular, or stripe-like structures may be chosen. Furthermore, the principle of dispersive color separation is not limited to the dispersive lenses, but the dispersive prisms or other dispersive elements may be used as well.

The diameters of the central circular and peripheral ring-shaped sensors can be calculated according to the focal lengths of the lens at respective color bands and the distance between the lens and the sensor, as will be obvious to a person skilled in the art.

The image sensor array may comprise an rectangular array of such color pixels, with row and column selection mechanism, pixel reset mechanism according to selected time interval, pixel architecture comprising a closed photo diode corresponding to each element, with active area shaped in circular, ring-shaped or other necessary shape, source follower buffer transistor for the read-out and analog to digital (AID) converter or converters for the read out, as known in the art.

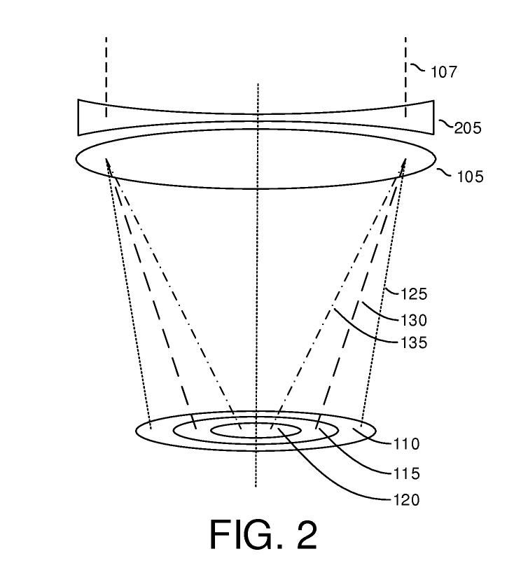

FIG. 2 illustrates another invention of this disclosure, which is the amplification of dispersion by a stack of converging and diverging lenses with different dispersion.

In the prior art, the combination of flint and crown lenses was used to reduce the chromatic aberrations. For that purpose the low-dispersive (crown glass) converging lens was combined with weaker, but high dispersive (flint glass) diverging lens. In the resulting system the converging lens had more optical power than the diverging lens, but the dispersions of same magnitude and opposite sign of mutually eliminated each other creating achromatic pair

[Interestingly, that creation of an achromatic pair, and legal battles of John Dollond and his son Peter Dollond regarding the patent writes on them in 1758-1789 in London, immediately preceded creation of US patent system in 1790-1793].

In the present invention, we suggest using the opposite combination of the lenses, namely the converging lens from high-dispersive flint glass, and the diverging lens of low-dispersive crown glass, to create a ‘chromat’ pair. The goal of prior art achromat was to eliminate chromatic aberration.

However, the goal the invented chromatic pair is the contrary: to create a lens, or micro-lens possessing the high chromatic aberrations. Diverging lens 205 on FIG. 2 is produced from low-dispersive refractive material, such as ‘crown’ glass, and converging lens 105 is produced of high-dispersive refractive material, such as ‘flint’ glass. The gap between lenses 105 and 205 is for clarity of illustration, and may be absent. The order of the lenses may be opposite, which means first in the optical path from the outside towards the pixel may be converging lens 105, and the second diverging lens 205. The optical stack may also consist of more than two lenses, for example from three lenses, arranged as converging-diverging-converging lense, or diverging-converging-diverging. One surface of the lenses may be flat, so that plano-concave, convex-convex, concave-plano, lenses, or any other arrangement using plano-concave, plano-convex, concave-concave, convex-convex and concave-convex lenses and their combinations may be used and are all covered by this discloser.

The lenses may be glued, attached together or manufactured by microlithography processes, including deposition of the mask material, exposure, development, thermal treatment, cleaning and other stages known in the art.

However the application of the disclosed novel structure of the lens composite designed and produced to possess the strong chromaticity, strong dispersion, chromatic aberrations is not limited to the disclosed circular color pixels, and may be used in other applications of optics and digital imaging. Traditionally the optical systems were designed to decrease the chromatic aberrations, and the combinations of the flint and crown glasses were chosen to mutually eliminate or at least significantly decrease total color dispersion and chromatic aberrations of the optical system. In the disclosed design the optical system is designed with the opposite goal—to increase the chromatic aberrations. The disclosed optical solution is intended for multiple emerging applications of digital imaging, optics, and electro-optics where the increased color dispersion and chromatic aberrations will be required. For example a camera optical lens with strong chromatic aberration will possess different focal lengths for different color bands. Acquiring two or more images with different lens focuses will allow to sequentially acquire different color bands, and to reconstruct the respective color layers and color image by further processing. For single acquired image, the objects at different distances will be in focus for different colors. For example the red layer of remote objects, green layer of intermediate objects and blue layer of near objects will be simultaneously focused.

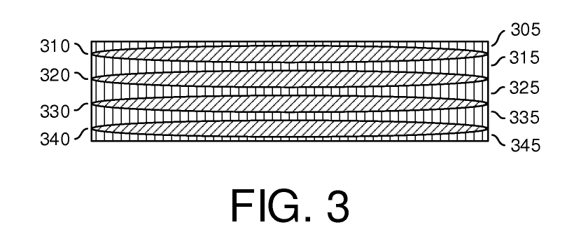

FIG. 3 illustrates another embodiment lens with enhanced chromatic dispersion. It has a layered structure, composed of sequentially arranged converging and diverging lenses, and multiple thin converging (310, 320, 330, and 340) and diverging (305, 315, 325, 335, and 345) lenses. The converging lenses should me manufactured from highly dispersive material, such as flint glass, while the diverging lenses should be manufactured from low-dispersive material, such as crown glass. The resulting structure is essentially flat element with stacked structure, possessing strong chromatic dispersion, and it can be used as a dispersive color separating element mounted above the concentric ring-shaped photo-sensors to form a concentric color pixel.

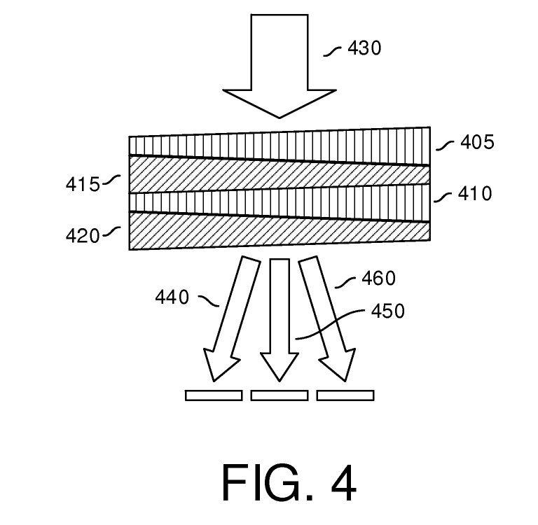

Another invention, disclosed here is the layered prism, created for strong chromatic dispersion, and consisting of alternating stack of thin prisms of flint and crown glass, as shown on FIG. 4. FIG. 4 illustrates the operation of the stack of prisms of interchanging directions, made from refractive materials of different dispersion in order to enhance the dispersion effect.

Arrow 430 schematically shows an incident beam of light. Prisms 405 and 410 have opposite orientation from prisms 415 and 420, to mutually compensate or decrease the light bending effect. Furthermore, prisms 405 and 410 are manufactured from crown glass with low dispersion (high Abbe number), while prisms 415 and 420 have high dispersion (low Abbe number), which results in accumulating color dispersion of the stack of prisms. Interchanging stack of prisms will possess a net effect of strong dispersion, as will be obvious to a person skilled in the art. Arrows 440, 450 and 460 illustrate the three beams of different color bands, such as red, green and blue. One can see, that the prisms are oriented in opposite directions, so that the prisms 415 and 420 will bend the light beam to the, while the prisms 405 and 410 will bend the light beam to the right on the plane of FIG. 4.

The goal of creating a stack of the prisms with opposite orientations and different values of chromatic dispersion is to accumulate the dispersion of several prisms while eliminate or decrease the net refractive light bending. So that the net effect will be stronger chromatic dispersion, with smaller light bending, comparing to the dispersion and bending of the single prism.

Therefore, what is claimed is:

1. A dispersive lens, composed of at least one converging and at least one diverging lens, where the converging lens manufactured from high-dispersive material and the diverging lens manufactured from low-dispersive material.

2. A dispersive lens of claim 1, comprising a stack of two converging lenses manufactured from high dispersive flint glass, and one diverging lens in between, manufactured from low dispersive crown glass.

3. The dispersive lens of claim 1, where multiple converging and diverging lenses are sequentially arranged in the layered structure.

4. An optical system, comprising at least one dispersive lens of claim 1.

5. An electro-optical system, comprising at least one dispersive lens of claim 1.

6. A color image sensor, using the dispersive lenses of claim 1 for at least partial color separation.

7. A color image sensor, using the dispersive lenses of claim 2 for at least partial color separation.

8. A color image sensor, using the dispersive lenses of claim 3 for at least partial color separation.

9. A dispersive prism with enhanced chromatic dispersion, assembled as a stack of two or more attached dispersive prisms, oriented in two opposite directions, where the prisms oriented in the first direction are manufactured from the low-dispersion material, while the prisms oriented in the second direction are manufactured from the high dispersion material.

10. An optical system, comprising at least one dispersive lens of claim 9.

11. An electro-optical system, comprising at least one dispersive lens of claim 9.

12. A color pixel, composed of at least the first and the second photo sensors, and a dispersive prism of claim 9, mounted above the said sensors so that the dispersive prism at least partially differentiates the color spectrums of the light reaching the first and the second photo sensors.

13. An image sensor, comprising an array of color pixels of claim 12.

14. A concentric pixel, comprising the center photo sensor surrounded by one or more concentrically arranged peripheral photo sensors.

15. A concentric pixel of claim 14, where the center photosensor is circular shaped, and one or more surrounding photo sensors are ring shaped.

16. A concentric pixel of claim 14, further comprising a dispersive microlens mounted above it, designed to separate the incident light by dispersion so, that one part of the light spectrum essentially falls onto the central photosensor, and other parts of the light spectrum essentially fall on the peripheral photo sensors.

17. An image sensor, comprising an array of concentric pixels of claim 14.

18. An image sensor, comprising an array of concentric pixels of claim 15.

19. An image sensor, comprising an array of concentric pixels of claim 16.
